(19) United States
(12) Patent Application Publication
(10) Pub. No.: US 2008/0302357 A1
(43) Pub. Date: Dec. 11, 2008

(54) Solar photovoltaic collector hybrid

(76) Inventor: Roger DeNault, Santa Cruz, CA (US)

Correspondence Address: Walt Froloff, 273D Searidge Rd, Aptos, CA, 95003, US

(21) Appl. No.: 11/810,246

(22) Filed: Jun. 5, 2007

(51) Int. Cl. F24J 2/04; H01L 31/042

(52) U.S. Cl. 126/704; 126/624; 136/244

(57) ABSTRACT

The present invention discloses a system for a hybrid solar energy collector comprising a CIGS photovoltaic energy collector, the photovoltaic energy collector being thermally coupled to an energy absorbing working fluid casing for flowing heat out to heat sink The solar radiation is trapped in the photovoltaic collector, generating electrical power from the CIGS photovoltaic array, The array is cooled by the working fluid transferring unproductive heat away from the photovoltaic array and into an exterior heat sink via the cooling fluid circuit, thus making the photovoltaic array more efficient, while adding another energy source. Where thermal collection is not beneficial, a floating platform supported CIGS PV array may be cost effectively cooled to increase efficiency, by harnessing wave energy from a wave power device to flow cooling or evaporative spray water over the panel.

### BACKGROUND

### Field of the Invention

The present invention generally relates to solar energy collectors and more specifically, to solar collectors using CIGS for photovoltaics, thermal working fluid heat collection and wave energy capture hybrid devices.

The general area of solar collectors is not new. Some solar cells include selective coating on the top surface which increase absorption of the light energy within the desired wavelength range. Moreover, optical coatings are commonly used to reflect light of undesirable wavelengths such as that within the infrared range in order to reduce excessive heating of the cell. Also, since only about 20% of absorbed radiation results in electric current, the other 80% is converted to heat. This heat then makes the photovoltaic element 10-20 percent less efficient, since increased cell temperatures generally result in a decrease in cell efficiency for producing electricity.

In the past there have been attempts to provide residential and industrial applications solar thermal collectors and solar photovoltaic cells, suitable for converting light energy into both electrical energy and thermal energy. These have had limited success mostly because of the added cost of the thermal portion designs and insufficient power output to cover these costs.

There have been some combined electrical and thermal solar collectors proposed. Some use flow tubes below plates, with thin perpendicularly heat-conductive web of rigidly connecting plate to flow tubes, inlet and outlet headers at opposite ends of flow tube, making parallel flow tubes below plates, to keep temperature gradients sufficiently low. These all have costs; flow tubes, flow tube construction, manufacturing and building collector, pumping fluid, and insufficient temperature removal.

Some proposed designs include a photovoltaic grid mounted on a copper plate that provide wider more uniform temperature dispersion across the plate and acts as a thermal radiator when the apparatus is used in the radiant cooling mode. This and a plurality of interconnected heat transfer tubes located within the enclosure and disposed on the plane below the copper plate but conductively coupled to the copper plate for converting the solar energy to thermal energy in a fluid disposed within the heat transfer tubes. Fresnel lenses can be affixed to the apparatus on mountings for concentrating the solar energy on to the photovoltaic grid and functioning as a passive solar tracker. These suffer from complexity and cost of manufacturing, requiring interconnected heat transfer tubes, a Fresnel lens, resistance calculations and bridge circuitry and more. Electronics and sensors have become better and cheaper, and the methods used are not current, keeping costs higher than other solutions. Others use flexible thermal solar collectors, instead of rigid collectors, but these are more expensive because of the flexibility of material and mounting is required.

Still other designs hybridize solar energy collectors with a photovoltaic collector that generates electricity and a thermal collector which is semi-transparent, utilizing shorter-wavelength radiation while selectively transmitting medium- and long-wavelength radiation to the thermal collector. The collectors are separated by a thermal insulating barrier and have a transparent exterior glass surface and a transparent body, adding cost. These have photovoltaic energy collector thermally insulated from heat generated by the thermal energy collector, instead of optimally transferring the PV energy collector heat directly to the thermal collector for the dual purpose of cooling the PV and collecting thermal energy.

Still other designs use a substantially unsealed enclosure, an array of photovoltaic cells for converting solar energy to electrical energy located within the enclosure, and a plurality of interconnected heat collecting tubes located within the enclosure and disposed on the same plane as the array of photovoltaic cells for converting solar energy to thermal energy in a fluid disposed within the heat collecting tubes. These again, are costlier tube constructs with interconnected heat collecting tubes located within the enclosure and disposed on the same plane as the array of photovoltaic cell, instead use open channels, slab geometry conduit and freon or other refrigerant gas working fluid. Open channel surface flow or slab geometry conduits with working fluid liquid or gas or both in the enclosure, or convective and conductive or capillary action energy transfer means may prove less expensive.

Single thin-film solar panel technology is emerging, composed of flexible aluminum substrate, electrically conductive back metal contact layer which could be deposited on the anodized flexible aluminum substrate. An anodized surface electrically insulates the aluminum substrate from the electrically conductive back metal contact layer; a semiconductor absorber layer is deposited on the back metal contact. The semiconductor absorber layer is constructed from a film selected from the group of metals composed of Copper, Indium, Gallium and Selenium, thus its name, CIGS thin film. These are emerging but not yet competitive with the conventional photovoltaic solar panels offered. The CIGS suffer from the deficiency that as they heat up thermally, they become less efficient and therefore less cost effective. Thus CIGS photovoltaic panels suffer from high cost and lower efficiency at higher temperatures.

Some companies have been engaged in the research and development of thin-film Cu(In,Ga)Se2 (CIGS) photovoltaic technology since 1991. Some have pursued a vacuum-based approach to CIGS production, using linear source technology and standard soda-lime glass substrates. The choices result in layers having controllable purity and low physical defects, and production without significant hazards. Considerations such as these are important in helping to minimize the processing costs of CIGS. Thin film PV technologies have advanced considerably, however, for technologies to survive, they must also perform well commercially. As a result of such fiscal pressures, a big market player shut down two sophisticated thin film lines using alternate methods. In some cases it maybe premature to discard some thin film CIGS technologies until all the costs and benefits are all totaled. Perhaps the highest yield technology will would be costlier than a hybrid with the lower cost CIGS but less efficient. This CIGS technology coupled with a complementary solar technology, may increase the total collector yield or give the total cost below a cost/benefit improvement over the higher efficiency CIGS technology. Thus, what is needed is hybrid technology which can be scaled and complementary to the CIGS thin film technology to maximize the utility of solar technology.

Water is becoming a more precious commodity, in support of every growing population. However, in California alone, typical reservoir surface area normally exposes 647,200 acres, shrinking substantially in drought years and appreciably in the autumn of a normal year. The total average annual evaporation from these areas is 2.3 million acre-feet. This amounts to an average evaporation from reservoirs, in the neighborhood of 60 inches averaged over the whole state. Thus a need for water retention can be satisfied if the surface were partially covered, as vaporization occurs across the solar exposed water surface. But to cover the water surface, would be prohibitively costly and unjustified, therefore it is not contemplated. Recreation use would be affected, but there are bodies of water that do not have recreational use or only partial use. Therefore, what is needed are ways of saving water and capturing the solar energy generally rendered useless in evaporation.

Generally, photovoltaic CIGS solar panels need a way of cooling the cell array in a cost effective manner and solar hybrid collectors need to be manufactured and made cheaper. Methods and designs for heat transfer and cooling photovoltaic without expensive insulation, manufacturing costs and smarter heat transfer designs, can harness thermal energy from the photovoltaics and collect the heat where it is needed. Such designs can be incorporated into photovoltaic raft structures that both shade reservoir water and produce higher efficiency PV generated electricity.

Expensive real estate has priced out placing solar collectors in many markets. Hence many residential and commercial applications of solar are not contemplated. Meanwhile, precious water is lost by evaporation from solar energy action. What is needed are cheaper and more efficient solar hybrids, solar hybrids which can solve other problems such as water loss due to evaporation, or solar hybrids which can take advantage of other forms of energy.

### SUMMARY

The present invention discloses a system for a hybrid solar energy collector comprising: a outer thermal collector housing with one way exterior surface to trap solar radiation, housing a flat CIGS photovoltaic energy collector, the photovoltaic energy collector being thermally coupled to an energy absorbing working fluid casing for flowing heat out to heat sink The solar radiation is trapped in the collector, generating electrical power from the CIGS photovoltaic array. The array is cooled by the working fluid transferring unproductive heat away from the photovoltaic array and into an exterior heat sink via the cooling fluid circuit, thus making the photovoltaic array more efficient, while adding another energy source from waste heat. A water floating collector is also presented, adding yet the wave energy into the collector array. These may be more cost effective to cool the CIGS PV array panels using transpiration cooling spray pumped from onboard hybrid wave or wind power sources.

### BRIEF DESCRIPTION OF DRAWINGS

Specific embodiments of the invention will be described in detail with reference to the following figures.

FIG. 1 is a cross sectional diagram illustrating an a solar photovoltaic using CIGS layered on a thermal collector according to an embodiment of the present invention.

FIG. 2 shows a thermal collector element for fluid heat transfer in accordance with an embodiment of the invention.

FIG. 3. illustrates CIGS PV with straight flow through collector hybrid a in accordance with an embodiment of the invention.

FIG. 4 illustrates a floating solar hybrid in accordance with an embodiment of the invention.

FIG. 5 illustrates a floating solar hybrid with wave energy booster in accordance with an embodiment of the invention.

FIG. 6 illustrates a wave energy booster piston-cylinder in accordance with an embodiment of the invention.

FIG. 7 illustrates a floating solar hybrid array in accordance with an embodiment of the invention.

FIG. 8 illustrates a tethered floating solar hybrid array profile view in accordance with an embodiment of the invention.

FIG. 9 illustrates a double side “W” reflector housing solar hybrid perspective view in accordance with an embodiment of the invention.

FIG. 10 illustrates a double side “W” reflector housing solar hybrid front view in accordance with an embodiment of the invention.

### DETAILED DESCRIPTION

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

### Objects and Advantages

The present invention is a system and method of converting solar energy to electrical energy via several parallel paths acting concurrently.

Accordingly, it is an object of the present invention to provide a more efficient and cost effective solar technology, one that uses CIGS in combination with thermal collectors.

It is another object of the present invention to provide embodiments designed for water surfaces, to take advantage of more affordable locations for solar arrays, reduce fresh water loss from evaporation, harness wave energy in parallel to increase efficiency, provide a heat sink cooling photovoltaics to increase conversion efficiency, provide a floating power source and for other benefits from locating solar platforms on inland or ocean sites.

### Embodiments of the Invention

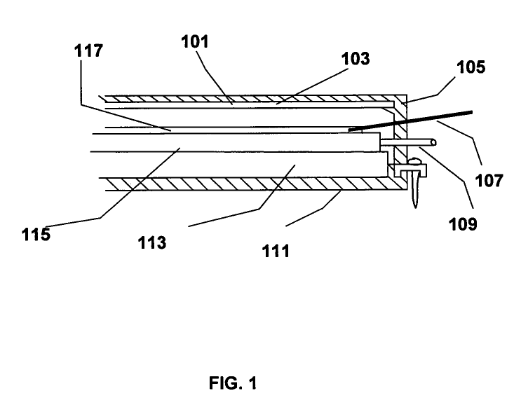

FIG. 1 is a cross sectional diagram illustrating an a solar photovoltaic using CIGS layered on a thermal collector according to an embodiment of the present invention. A thin semi-transparent or one-way mirror layer 101 covers a glass or plastic collector cover 103, held in place by a shallow housing 105 top and bottom 111, not necessarily rectangular, for capturing impinging solar energy not necessarily only visible spectrum. The CIGS thin film layer 117 is deposited on a thermal conducting 115 working fluid casing 115, from which a fluid can be forced or gravity fed through an opening 109. In some configurations, the cooling can be panel externally applied fluid spray. The thermal conducting fluid casing 115 may be supported by insulation 113, to encourage the heat to be collected by the fluid. Solar radiation is trapped after penetrating the one-way mirror layer 101, bouncing around until it is absorbed by the CIGS layer 117, where the electrical power is transferred 107 to an outside storage cell, or thermally conducts to the working fluid layer 115, for hot water use or a working fluid thermodynamic energy transfer to a temperature sink, known to those skilled in the art. Thus an optimum recipe for the CIGS thin film is not necessary from the CIGS standpoint, as an aspect of the invention is to be able to use the less costly less efficient CIGS thin films in a higher efficiency hybrid solar design.

Many methods of CIGS deposition; spray, sputtering, layers, rolling, special treatment, buffer combinations, buffer layers, junction formations, material compositions, composites, patterning, etc and substrates; production, interconnect methods, fabrication, etc are known to those skilled in the art. Some create higher efficiencies but may have higher costs. An objective of the invention is to use the least expensive approach which with the thermal heat harnessed as a part of the solar hybrid system, yields the highest total solar energy capture per unit cost. As with most all PV, the CIGS efficiency improves where the temperature can be maintained within certain levels. Thus, the temperature extracted in heat from the CIGS panel and harnessed in the thermal heat portion, the overall unit efficiency increases.

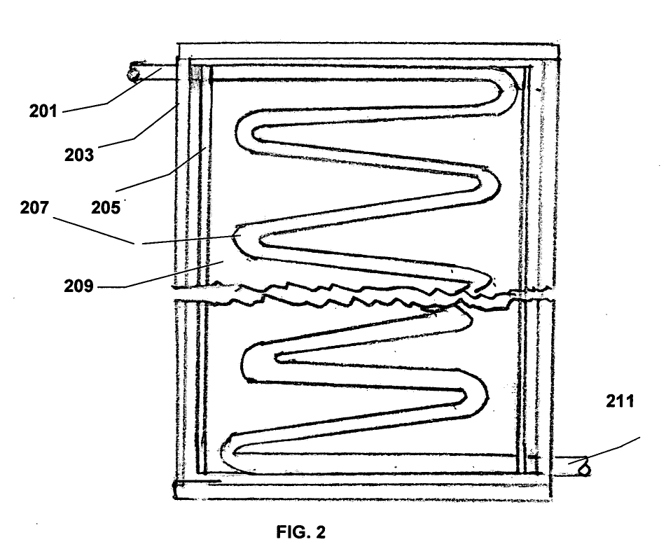

FIG. 2 shows a thermal collector element for fluid heat transfer in accordance with an embodiment of the invention. The outlet 201 of the working fluid can be vertically higher than the working fluid inlet 211. The working fluid casing 209 is constructed separate to the channels 207 and bonded or in one slab type construction upon which the CIGS layer can be deposited. The collector may by housed in a frame 203 and enclosed by semi-transparent cover facing the solar exposure and insulated on the opposite side to retain maximum heat removal through the working fluid.

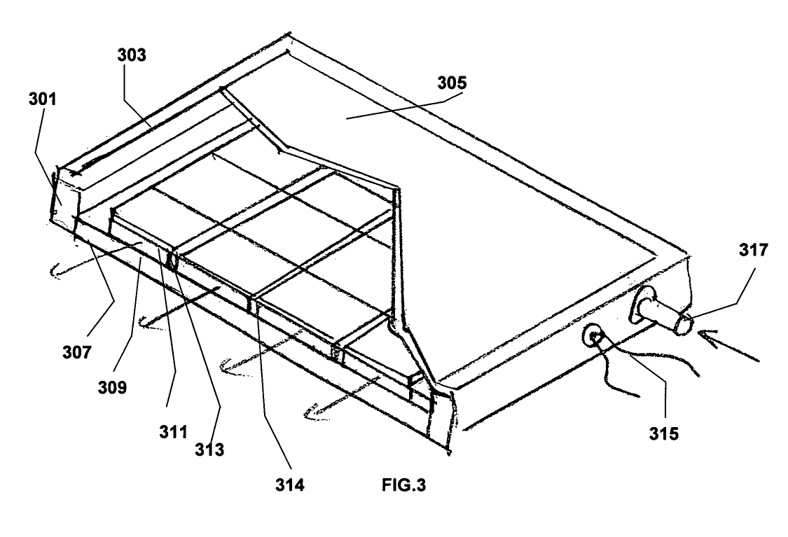

FIG. 3 illustrates CIGS PV with straight flow through collector hybrid a in accordance with an embodiment of the invention. A housing frame 301 supports a lip 303 firmly holding a slidable semi-transparent one-way plastic or glass cover. The housing bottom 307 supports insulation 309 upon which working fluid channels 311 rest. These are bonded with thermal conducting materials 313 to the CIGS cells 314, which are connected electrically to conduct the electrical energy 315 out. The CIGS cells 314 can be manufactured in several ways, extrusion, printing press plastic membrane, liquid paint form deposit, sputtering onto stainless steel sheets or flexible foil, and other manufacturing processes using CIGS coatings known to those skilled in the art. Working fluid enters at an opening 317 and can flow naturally with gravity or force pumped against gravity inclines.

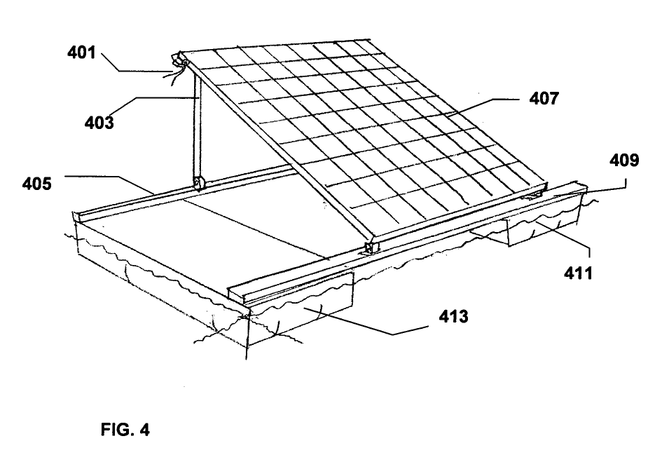

FIG. 4 illustrates a floating solar hybrid in accordance with an embodiment of the invention. A primitive structure 409 405 403 keeps the solar cell array 407 floating above the water surface. The frame structure 409 405 403 is attached to pontoons 413 411 and electrical energy can be conducted out 401 by cable or wire 401. The frame structure 409 402 405 can be more complex, having a motor elevating support beam 403 or withdrawing the support beam 403 and elevating support beams from the opposite side, under control of a automatic solar tracker and sensor. The automatic solar tracking can add 20%-40% more electrical power from the photovoltaics. Not shown are alternative exterior panel cooling from siphoned water spray, to contain the PV temperature yet another way, and without a contained thermal fluid.

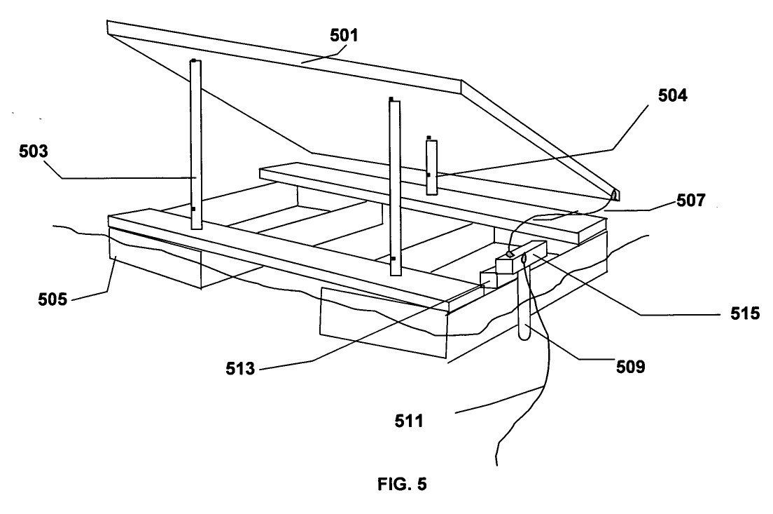

FIG. 5 illustrates a floating solar hybrid with wave energy booster in accordance with an embodiment of the invention. The solar panel 501 is shown supported 503 504 by simple rigid structures which can easily be motorized by one degree of freedom to adjust the panel 501 to a solar tracker, keeping the panel at optimal angle to the sun. The solar panel 501 floats on pontoon 505 structures which can be made from many materials and geometries. The solar panel 501 is shown above the water surface but since solar energy can transfer through water, a partially submerged embodiment can be contemplated. The solar photovoltaic cell array produces electrical energy transferred by wire or cable 507 to a junction or converter 513, for external distribution 511. A wave energy capture tube-piston device 509, known to those skilled in the art, is coupled to the float 505 and must be at least partially submerged to trap the wave energy from the surface proximity. The wave energy tube-piston device 509 is directly coupled to a power extractor 515, also known to those skilled in the art. Power from the wave device can be additive to the outgoing electrical power 511 at the converter/junction box 513 or diverted toward the solar hybrid functions such as pumping cooling water through the solar panel, 501, evaporative spray cooling, powering the tracking device, or other on-board needs. Cooling of the solar array can boost electrical power output another 10%-15%, which can be a significant improvement even subtracting the power lost to pumping cooling fluid over the panel.

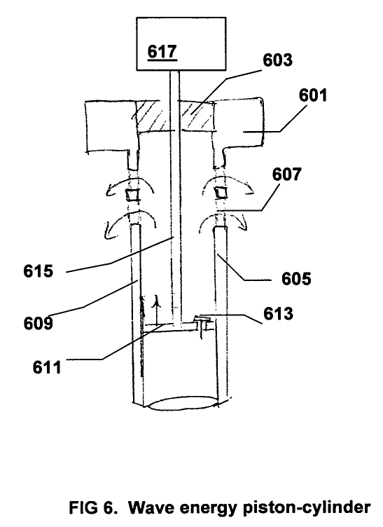

FIG. 6 illustrates a wave energy booster piston-cylinder in accordance with another embodiment of the invention. The wave energy device is enclosed in a tube 605 with a piston 611 in a cylinder catcher 609, piston 611 coupled to a power converter 617 via a shaft 615. Wave action pushes the piston 611 up as the wave impinges and down the tube 605 as the wave recedes, draining fluid through openings 607 in the tube 605. A small check valve 613 can reduce piston 611 resistance to wave receding. The power converter can be air-turbine, oil motor coupling-gearbox, or direct conversion, harnessing the moving piston energy from wave action to electrical energy. The power can be additive to outgoing contribution or on panel use for evaporative spray cooling of the panel for increasing panel efficiency. Not shown are analogous small wind power mills or turbines which can harness smaller amounts of wind energy for on panel or off panel contribution.

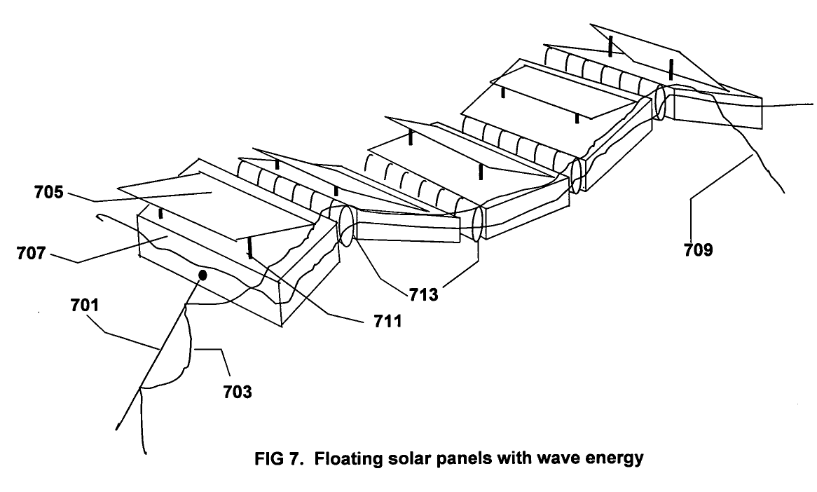

FIG. 7 illustrates a floating solar hybrid array in accordance with an another embodiment of the invention. Solar collect panels 705 are coupled to floatation platforms 707 using support structures 711 which can be extended, or retrieved through a rack-an-pinion controlled solar tracker. The platform 711 would be coupled to another platform through a wave energy hinged joint device 713 known to those skilled in the art.

The solar photovoltaic panels transmit the electrical power to shore via cable 703. As a wave passes down the length of floatation panel 707 array, the hinged joints 713 on the power conversion modules, known to those skilled in the art, allow the floatation panels 707 to move up and down and side to side. The motion of the solar floatation platforms 707 relative to each other, drives pumps that turn generators inside the hinge wave energy harnessing device 713. The electricity flows via a cable 703 to a shore-based grid. Some harnessed energy can be used to pump cooling or evaporative spray water over the solar panels 705 to increase their efficiency, as cooling CIGS cells to optimal temperatures can increase efficiency by 10%-20%. For some situations, it is estimated that the power needed to pump cooling or evaporative spray water over the panels is much less than the incremental power produced by the photovoltaics at the cooler temperatures, thus synergistically justifying the energy cost of pumping.

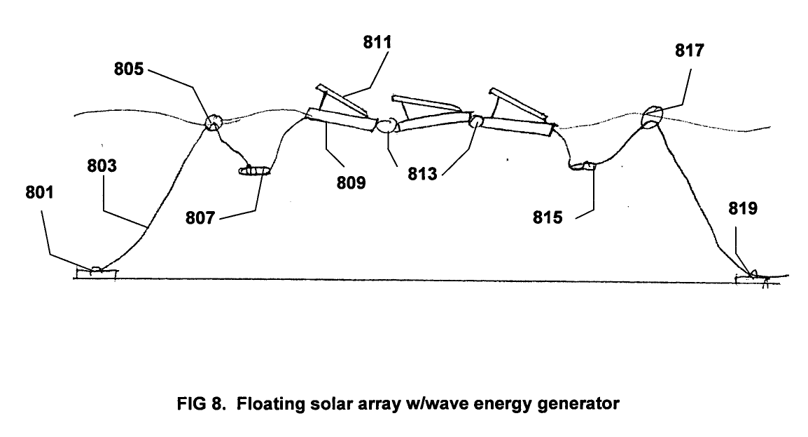

FIG. 8 illustrates a tethered floating solar hybrid 811 809 array profile view in accordance with an embodiment of the invention. The solar photovoltaic panel 811 is supported on the floatation platform 809 coupled by the wave energy devices 813. The array must be flexibly anchored to allow wave action be harnessed by the array simultaneously with electrical power from the photovoltaic array. To add flexibility, the hybrid array ends are tethered to submerged free floaters 807 815 and then to surface float anchors 805 817 for a less active cable 803 segment connection to the bottom anchors 801 819. This type of flexible anchor arrangement is known to those skilled in the art. The water depth and the wave action are factors which is considered in such an arrangement, as the cable 803 and power transmission costs play a roll in how far offshore the array is flexibly anchored 801 819

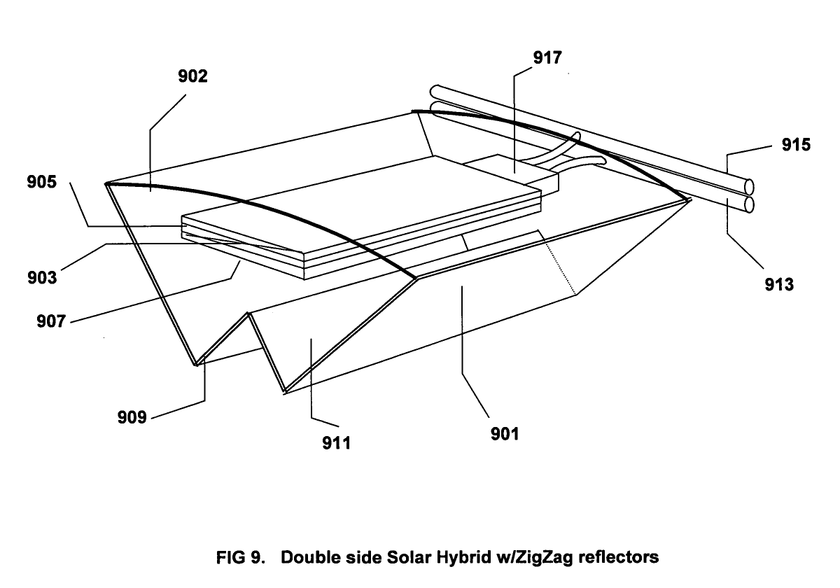

FIG. 9 illustrates a double side “W” reflector housing solar hybrid perspective view in accordance with an another embodiment of the invention. The housing 901 909 911 is formed in the configuration of the letter “W” from the front edge 909 and extruded along a longitudinal axis in parallel with the CIGS coated photovoltaic array 903 907. The “W” housing configuration would have a reflecting inside surface 901 911 such that all solar radiation not impinged or reflected from the CIGS coated photovoltaic cell surface 903 directly facing the sun side, would be trapped and reflected onto the opposite CIGS coated photovoltaic side facing cell array 907. CIGS coatings constituting the photovoltaic cell array panels 903 907 would be electrically coupled to storage and/or converters for internal or external electrical power. The CIGS photovoltaic panel is further cooled to a temperature to optimize the power out. The cooling can be provided by a simple fluidic channel 905 between the two opposing panels 903 907 flowing coolant in 913 and out 915 coupled through and adaptor 917. The cooling fluid would deliver the heat to a water heater or other thermo fluid exchanger.

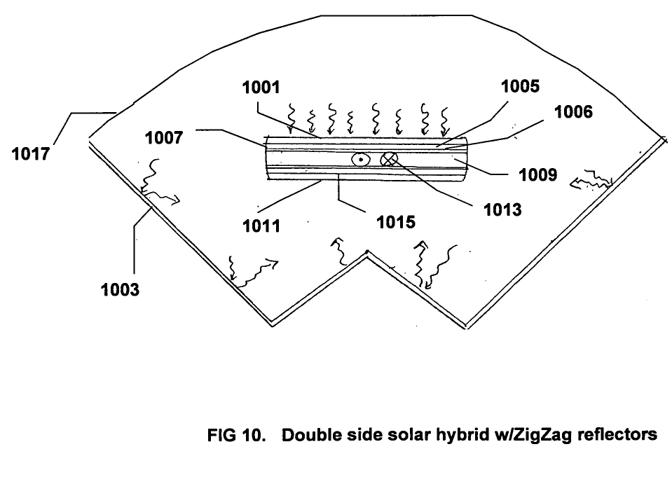

FIG. 10 illustrates a double side “W” reflector housing solar hybrid front view in accordance with an embodiment of the invention. The CIGS photovoltaic cell is coated with a layer of CIGS 1001 material on substrate 1005 material which is known to those in the art. The substrate 1005 is bonded by a thermal conducting agent 1006 to a thermal conducting fluid channel 1007, channel made of material with good thermal conducting properties, for conducting heat to a flowing cooling thermofluid 1009 through the channel having inlet 1013 and outlet conduits flowing the cooling thermofluid to a heat sink. The channel 1007 can be partially constructed from thin metallic sheets, also acting as the substrate for the CIGS photovolatiac. Although shown as such, the channel cross section need not be necessarily rectangular and can be many other or variable cross section. Moreover, many other thermal conducting materials can be used. Minimum cost material and fabrication will dictate materials. The thermofluid 1009 can be water, coolant, refrigerant or other, where heat transfer properties efficiently retain the heat from the photovoltaic layers and quickly move out reducing the photovoltaic cell 1001 temperature to a more energy efficient range. The opposite side of the channel will be like wise layered with CIGS layer 1011 first to catch non direct impinging solar radiation, and held to a substrate 1015 which is bonded by a thermal conducting agent to the channel wall 1007. The channel can be the same as the opposite side or a partitioned channel carrying cooling fluid 1009 in the opposite direction.

The housing 1003 is configured in a shallow “W”, with a reflecting inside surface, for catching solar rays not impinging on the outer cell 1001 structure, but finding the opposite CIGS surface 1011 by reflection. The “W” housing 1003 configuration provides a structurally stronger housing less costly materials and manufacturing. Using a shallow “W” housing can focus solar radiation from a 3 to 1 advantage, since the area of the “W” will reflect light to the smaller area of the array 1001. not a strict requirements, as drain holes can be designed into the “W” shape corners should the collect rain or other fluids in the trough like housing structure.

Therefore, while the invention has been described with respect to a limited number of embodiments, those skilled in the art, having benefit of this invention, will appreciate that other embodiments can be devised which do not depart from the scope of the invention as disclosed herein. Other aspects of the invention will be apparent from the following description and the appended claims.

What is claimed is:

1. A hybrid solar energy collector system comprising:
CIGS photovoltaic on a substrate for photovoltaic energy collection,
the photovoltaic energy collector being thermally coupled to an energy absorbing working fluid channel for removing heat to an exterior heat sink,
whereby solar radiation is trapped in the collector generating electrical power from the CIGS photovoltaic array, which is cooled by the working fluid transferring heat away from the photovoltaic collector and into an exterior heat sink.

2. A system as in claim 1 further comprising a concave outer semi-transparent one-way housing exterior surface.

3. A system as in claim 1 further comprising an outer thermal collector housing with one way surface to trap solar radiation.

4. A system as in claim 1 further comprising a liquid or gas working fluid.

5. A system as in claim 1 further comprising coupling the CIGS photovoltaic substrate surface to thermal working fluid channel with thermally conductive bonding.

6. A system as in claim 1 further comprising rolling the CIGS material onto the substrate.

7. A system as in claim 1 further comprising sputtering the CIGS material onto the substrate.

8. A system as in claim 1 further comprising a supporting floatation platform for placement on a water surface.

9. A system as in claim 8, further comprising a wave energy device for harnessing available wave energy imparted to the platform.

10. A system as in claim 9, further comprising coupling platforms for harnessing available wave energy from the coupled platforms.

11. A system as in claim 9, further comprising pumping cooling fluid through the collector by using wave power derived from the floatation platform, thereby cooling the photovoltaic array for increased CIGS photovoltaic efficiency.

12. A hybrid solar energy collector system on a floating platform comprising:
an on-board photovoltaic solar energy panel,
an on-board wave energy generator for harnessing platform rocking motion from wave action,
siphon from top of panel to cooling water source, and
electrical converter and switching mechanism for pumping cooling or evaporative spray water over the panel,
whereby panel temperature from solar radiation is reduced by flowing or spraying cooling water over the panel thereby increasing panel conversion efficiency.

13. A hybrid solar energy collector system on a floatation platform as in claim 12 further comprising using on-board wind energy devices harnessing power to cool the photovoltaic array for increased photovoltaic efficiency.
